(19) United States
(12) Patent Application Publication
(10) Pub. No.: US 2024/0274581 A1
(43) Pub. Date: Aug. 15, 2024

(54) SEMICONDUCTOR PACKAGE

(71) Applicant: Samsung Electronics Co., Ltd., Suwon-si (KR)

(72) Inventors: Dohoon KIM, Suwon-si (KR); Seungmin KIM, Suwon-si (KR)

(73) Assignee: Samsung Electronics Co., Ltd., Suwon-si (KR)

(21) Appl. No.: 18/437,570

(22) Filed: Feb. 9, 2024

(30) Foreign Application Priority Data
Feb. 13, 2023 (KR) 10-2023-0018983

(51) Int. Cl. H01L 25/065; H01L 23/00; H01L 23/31; H01L 23/498; H10B 80/00

(52) U.S. Cl. CPC H01L 25/0657; H01L 23/3128; H01L 24/08; H01L 24/16; H01L 24/32; H01L 24/48; H01L 24/73; H01L 23/49822; H01L 2224/08235; H01L 2224/16145; H01L 2224/16227; H01L 2224/16238; H01L 2224/32145; H01L 2224/32225; H01L 2224/48227; H01L 2224/73265; H01L 2225/0651; H01L 2225/06513; H01L 2225/06517; H01L 2225/06541; H01L 2924/1431; H01L 2924/1436; H10B 80/00

(57) ABSTRACT

A semiconductor package includes a package substrate, and a first semiconductor chip positioned on the package substrate. The first semiconductor chip includes a first inactive layer and a first active layer. The first inactive layer includes a high-density region, and the high-density region of the first inactive layer has a higher density than densities of other regions of the first inactive layer.

### CROSS-REFERENCE TO RELATED APPLICATION

This application is based on and claims priority under 35 U.S.C. § 119 to Korean Patent Application No. 10-2023-0018983, filed on Feb. 13, 2023, in the Korean Intellectual Property Office, the disclosure of which is incorporated by reference herein in its entirety.

### BACKGROUND

Some example embodiments of the inventive concepts relate to a semiconductor package, and more particularly, to a semiconductor package for protecting an active layer against a radioactive material.

Atoms included in a packaging material emit alpha particles during spontaneous radioactive decay. As the emitted alpha particles pass through a silicon substrate, energy is lost and charge-hole pairs are formed as free carriers. These free carriers may collect at circuit nodes and severely degrade a voltage level of a stored signal. That is, when free carriers are within a depletion storage region or a diffusion length of a capacitive voltage node, the free carriers may be collected by storage elements or voltage nodes, and thus, data errors may occur due to a change in the state of information present in the storage elements or voltage nodes. Recently, for high integration of semiconductor packages, the thickness of semiconductor chips has been reduced. Due to the reduction in the thickness of the semiconductor chips, a situation in which alpha particles cause data errors in semiconductor chips has increased.

### SUMMARY

Some example embodiments of the inventive concepts provide a semiconductor package in which the occurrence of data errors is suppressed or reduced in likelihood of occurrence.

The inventive concept provides a semiconductor package in which alpha particles are prevented or reduced in likelihood of reaching an active layer of a semiconductor chip.

In addition, the technical problems to be solved by the technical spirit of the inventive concept are not limited to the aforementioned problems. Other problems will be clearly understood by those of ordinary skill in the art from the following descriptions.

According to an example embodiment of the inventive concepts, there is provided a semiconductor package including a package substrate, and a first semiconductor chip on the package substrate, the first semiconductor chip including a first inactive layer and a first active layer, wherein the first inactive layer includes a high-density region, and the high-density region of the first inactive layer has a higher density than densities of other regions of the first inactive layer.

According to another example embodiment of the inventive concepts, there is provided a semiconductor package including a redistribution structure, and a semiconductor chip on the redistribution structure, the semiconductor chip including an inactive layer and an active layer, wherein the inactive layer includes a buried doped region, the buried doped region is doped with high-density impurities, and a density of the high-density impurities is higher than silicon.

According to another example embodiment of the inventive concepts, there is provided a semiconductor package including a package substrate, a first semiconductor chip on the package substrate, the first semiconductor chip including a first inactive layer and a first active layer, and a molding layer on the package substrate, the molding layer surrounding the first semiconductor chip, wherein the first inactive layer includes a high-density region doped with high-density impurities having a higher density than silicon, a density of the high-density region of the first inactive layer is higher than densities of other regions of the first inactive layer, the high-density region is spaced apart from the first active layer and is between the package substrate and the first active layer, and a concentration of the high-density impurities doped in the high-density region decreases in a direction toward the first active layer.

### BRIEF DESCRIPTION OF THE DRAWINGS

Some example embodiments of the inventive concepts will be more clearly understood from the following detailed description taken in conjunction with the accompanying drawings in which:

FIG. 1 is a schematic cross-sectional view of a semiconductor package according to some example embodiments;

FIG. 2 is an enlarged view of a region II of FIG. 1;

FIG. 3 is a schematic cross-sectional view of a semiconductor package according to some example embodiments;

FIG. 4 is a schematic cross-sectional view of a semiconductor package according to some example embodiments;

FIG. 5 is a schematic cross-sectional view of a semiconductor package according to some example embodiments;

FIG. 6 is a schematic cross-sectional view of a semiconductor package according to some example embodiments;

FIG. 7 is a schematic cross-sectional view of a semiconductor package according to some example embodiments;

FIG. 8 is a schematic cross-sectional view of a semiconductor package according to some example embodiments;

FIG. 9 is a schematic cross-sectional view of a semiconductor package according to some example embodiments;

FIG. 10 is a schematic cross-sectional view of a semiconductor package according to some example embodiments;

FIG. 11 is a schematic cross-sectional view of a semiconductor package according to some example embodiments;

FIG. 12 is a schematic cross-sectional view of a semiconductor package according to some example embodiments; and

FIG. 13 is a schematic cross-sectional view of a semiconductor package according to some example embodiments.

### DETAILED DESCRIPTION

Example embodiments in accordance with the inventive concepts may have various modifications and various forms, and thus, some example embodiments will be illustrated in the drawings and described in detail. However, this is not intended to limit the embodiments to specific disclosed forms.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

When an element is referred to as “on” another element, it may include not only “directly on,” “directly under” “directly on a left surface or right surface” in a contact manner, but also situations where intervening elements are present between the element and the other element (e.g., the element in a non-contact manner is on, under, at a left surface, or at a right surface of the other element). In contrast, when an element is referred to as being “directly on” or another element, there are no intervening elements present. Other words used to describe the relationship between elements or layers should be interpreted in a like fashion (e.g., “between” versus “directly between,” “adjacent” versus “directly adjacent,” “connected” versus “directly connected”, “above” versus “directly above”). Singular forms include plural forms unless apparently indicated otherwise contextually. When a portion is referred to as “comprises” a component, the portion may not exclude another component but may further include another component unless stated otherwise.

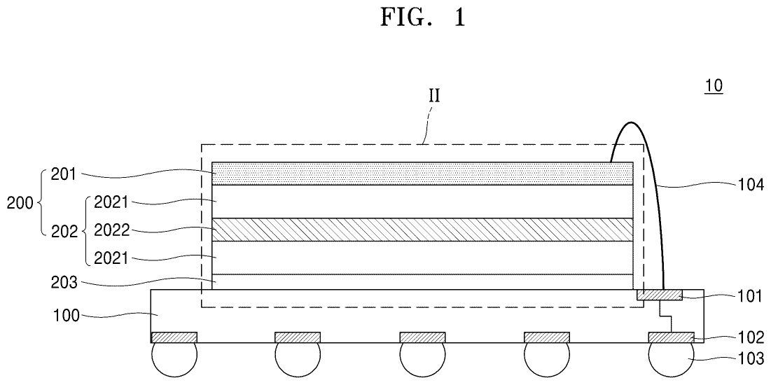

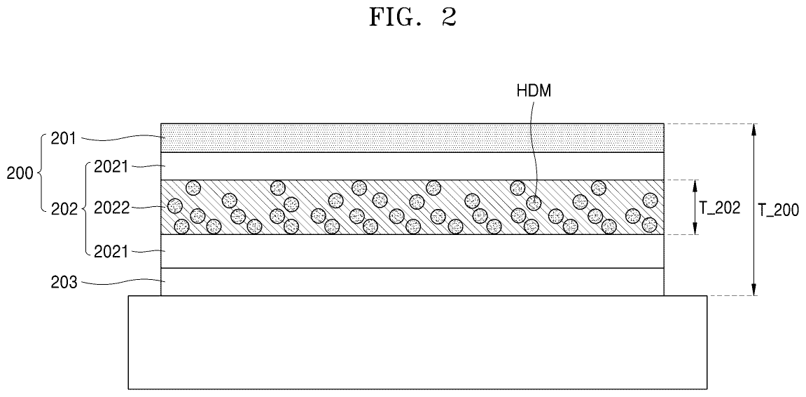

FIG. 1 is a schematic cross-sectional view of a semiconductor package 10 according to some example embodiments. FIG. 2 is an enlarged view of a region II of FIG. 1.

Referring to FIGS. 1 and 2, the semiconductor package 10 may include a package substrate 100 and a first semiconductor chip 200.

The package substrate 100 may generally have a flat plate shape or a panel shape. The package substrate 100 may include upper and lower surfaces opposite to each other, and the upper and lower surfaces of the package substrate 100 may each be flat.

The package substrate 100 may include, for example, a printed circuit board (PCB). The package substrate 100 may include a core insulating layer, upper connection pads 101, lower connection pads 102, and external connection terminals 103.

The core insulating layer may include at least one material selected from a phenol resin, an epoxy resin, and/or polyimide. For example, the core insulating layer may include at least one material from among polyimide, flame retardant 4 (FR-4), tetrafunctional epoxy, polyphenylene ether, epoxy/polyphenylene oxide, bismaleimide triazine (BT), thermount, cyanate ester, and/or liquid crystal polymer.

The upper connection pads 101 may be provided on an upper surface of the core insulating layer, and the lower connection pads 102 may be provided on a lower surface of the core insulating layer. An internal wire configured to electrically connect the upper connection pads 101 and the lower connection pads 102 to each other may be provided inside the core insulating layer. For example, the upper connection pads 101 and the lower connection pads 102 may each include a metal or an alloy thereof, the metal including copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), and ruthenium (Ru).

The external connection terminals 103 may attached to the lower connection pads 102 of the package substrate 100. The external connection terminals 103 may be configured to electrically and physically connect the package substrate 100 and an external device to each other. The external connection terminals 103 may be formed from, for example, solder balls or solder bumps.

The first semiconductor chip 200 may be electrically connected to the package substrate 100. In some example embodiments, at least one of the upper connection pads 101 of the package substrate 100 and the first semiconductor chip 200 may be electrically connected to each other via a wire 104. That is, the package substrate 100 and the first semiconductor chip 200 may be electrically connected to each other using a wire bonding method.

The first semiconductor chip 200 may be arranged over the package substrate 100. The first semiconductor chip 200 may include a first active layer 201 and a first inactive layer 202. The first inactive layer 202 may be arranged over the package substrate 100, and the first active layer 201 may be arranged on the first inactive layer 202. That is, the first active layer 201 may be spaced apart from the package substrate 100 with the first inactive layer 202 therebetween.

The first active layer 201 may include a plurality of integrated elements. The plurality of integrated elements of the first active layer 201 may include memory elements or logic elements.

For example, the memory elements may include dynamic random access memory (DRAM), static random access memory (SRAM), flash memory, electrically erasable and programmable read-only memory (EEPROM), phase-change random access memory (PRAM), magnetic random access memory (MRAM), and/or resistive random access memory (RRAM) elements.

For example, the logic elements may include AND, NAND, OR, NOR, exclusive OR (XOR), exclusive NOR (XNOR), inverter (INV), adder (ADD), buffer (BUF), delay (DLY), filter (FIL), multiplexer (MXT/MXIT), OR/AND/INVERTER (OAI), AND/OR (AO), AND/OR/INVERTER (AOI), D flip-flop, reset flip-flop, master-slaver flip-flop, latch, counter, and/or buffer elements. Also, the logic elements may include a central processing unit (CPU), a micro-processor unit (MPU), a graphic processing unit (GPU), and/or an application processor (AP).

In the first semiconductor chip 200 according to some example embodiments, the plurality of integrated elements of the first active layer 201 may include memory elements, for example, DRAM elements. For example, the first semiconductor chip 200 according to some example embodiments may be a DRAM chip. According to some example embodiments, the first semiconductor chip 200 is a DRAM chip and may be used in a high bandwidth memory (HBM) package.

The first inactive layer 202 may include silicon (Si). However, a material of the first inactive layer 202 is not limited to Si. For example, the first inactive layer 202 may include another semiconductor element such as germanium (Ge), or a compound semiconductor such as silicon carbide (SiC), gallium arsenide (GaAs), indium arsenide (InAs), indium phosphide (InP), and/or the like.

The first inactive layer 202 may have a silicon on insulator (SOI) structure. For example, the first inactive layer 202 may include a buried oxide (BOX) layer. Also, the first inactive layer 202 may include various element isolation structures such as a shallow trench isolation (STI) structure.

The first inactive layer 202 may include a high-density region 2022 having a higher density than those of other regions of the first inactive layer 202. That is, the first inactive layer 202 may include regions having different densities. The first inactive layer 202 may include the high-density region 2022 and a reference region 2021. The reference region 2021 of the first inactive layer 202 may be a region that does not correspond to the high-density region 2022 of the first inactive layer 202. A density of the high-density region 2022 may be higher than a density of the reference region 2021.

In some example embodiments, the first inactive layer 202 may include a buried doped region doped with high-density impurities HDM. The high-density impurities HDM may have a relatively high density compared to a material constituting an undoped region of the first inactive layer 202. That is, a density of the buried doped region may be higher than a density of the undoped region of the first inactive layer 202. Hereinafter, the buried doped region may be referred to as the high-density region 2022, and the undoped region may be referred to as the reference region 2021.

In some example embodiments, the high-density region 2022 may extend in a direction parallel to a lower surface of the first inactive layer 202. In other words, the high-density region 2022 may have the same length and width as those of the first inactive layer 202. That is, the high-density region 2022 may include all horizontal regions of the first inactive layer 202 having an arbitrary height. Accordingly, the high-density region 2022 may be between the first active layer 201 and the package substrate 100. A horizontal width of the high-density region 2022 and a horizontal width of the first active layer 201 may have the same length.

In some example embodiments, the high-density region 2022 of the first inactive layer 202 may not be in contact with the first active layer 201. That is, the first active layer 201 may be spaced apart from the high-density region 2022 with the reference region 2021 therebetween.

In some example embodiments, the high-density impurities HDM doped in the high-density region 2022 of the first inactive layer 202 may have a relatively high density. That is, when a main material constituting a reference region of a first inactive layer is a first material, the high-density impurities HDM may have a higher density than that of the first material. In some example embodiments, the first material may be Si, and the high-density impurities HDM may be a material having a higher density than that of Si. For example, the high-density impurities HDM may be one of elements (for example, Ge and arsenic (As)) having an element number greater than that of Si.

In some example embodiments, a thickness T_202 of the high-density region 2022 of the first inactive layer 202 may be about 3 μm to about 7 μm. In some example embodiments, a thickness T_200 of the first semiconductor chip 200 may be about 40 μm to about 60 μm. In some example embodiments, the thickness T_202 of the high-density region 2022 may be 5 μm, and the thickness T_200 of the first semiconductor chip 200 may be 50 μm.

In the semiconductor package 10 according to some example embodiments, the high-density region 2022 may be between the first active layer 201 and the package substrate 100, such that an amount of radioactive materials (for example, alpha particles) generated in the package substrate 100 that reach the first active layer 201 may be prevented or reduced. In other words, radioactive materials generated in the package substrate 100 that pass through the first inactive layer 202 and reach the first active layer 201 may be prevented or reduced in amount by the high-density region 2022.

Hereinafter, example embodiments of a process of manufacturing the semiconductor package 10 is described.

A plurality of integrated elements may be formed on an upper surface of a semiconductor substrate through an exposure process, a doping process, and an etching process. That is, the first active layer 201 may be formed on the semiconductor substrate.

Next, a region of the semiconductor substrate, in which the first active layer 201 is not formed, that is, the first inactive layer 202 is placed facing upward, and the first inactive layer 202 may be removed through a polishing process (for example, a chemical physical polishing process), such that the first inactive layer 202 has a certain thickness. In some example embodiments, the polishing process of the first inactive layer 202 may be performed until the thickness T_200 of the semiconductor substrate is about 40 μm to about 60 μm.

Next, the first inactive layer 202 may be doped with high-density impurities HDM through an ion implantation process on an upper surface of the first inactive layer 202. The upper surface of the first inactive layer may be a surface opposite the first active layer 201. During the ion implantation process, a thickness of a region doped with the high-density impurities HDM may be adjusted by adjusting an intensity of a voltage. For example, the thickness of the region doped with the high-density impurities HDM may be about 3 μm to about 7 μm.

The high-density impurities HDM may include a material having a higher density than that of the semiconductor substrate. In other words, the high-density impurities HDM may be a material having a higher density than that of a material in an undoped region of the first inactive layer 202. Accordingly, the region doped with the high-density impurities HDM may be the high-density region 2022.

The high-density region 2022 may be doped with the high-density impurities HDM using an ion implantation method, and a concentration of the high-density impurities HMD doped in the high-density region 2022 may decrease in a direction away from the upper surface of the first active layer 202. That is, the density of the high-density region 2022 may gradually decrease in a direction toward the first active layer 201.

Next, the semiconductor substrate on which the first active layer 201 and the high-density region 2022 are formed, that is, the first semiconductor chip 200 may be attached to the package substrate 100. In this case, an adhesive layer 203 may be between the first semiconductor chip 200 and the package substrate 100 to attach the first semiconductor chip 200 to the package substrate 100. In some example embodiments, the adhesive layer 203 may include an adhesive film such as a direct adhesive film (DAF).

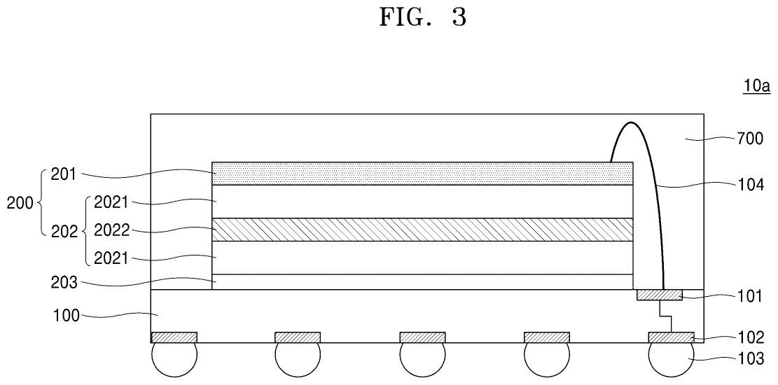

FIG. 3 is a schematic cross-sectional view of a semiconductor package 10a according to some example embodiments.

Referring to FIG. 3, the semiconductor package 10a may include a package substrate 100, a first semiconductor chip 200, and a molding layer 700.

Hereinafter, redundant descriptions between the semiconductor package 10a of FIG. 3 and the semiconductor package 10 (see FIG. 1) of FIG. 1 are omitted, and differences are described.

The package substrate 100 and the first semiconductor chip 200 of the semiconductor package 10a in FIG. 3 may be substantially the same as the package substrate 100 (see FIG. 1) and the first semiconductor chip 200 (see FIG. 1) of the semiconductor package 10 (see FIG. 1) in FIG. 1.

The molding layer 700 may be positioned above the package substrate 100. The molding layer 700 may surround the first semiconductor chip 200. For example, the molding layer 700 may be in contact with a surface of the first semiconductor chip 200 except for a surface in contact with the package substrate 100. That is, the molding layer 700 may cover side and upper surfaces of the first semiconductor chip 200.

The molding layer 700 may include, for example, an organic insulating material including an epoxy resin, a silicone resin, or a combination thereof. The molding layer 700 may include, for example, an epoxy mold compound (EMC). In some example embodiments, a side surface of the molding layer 700 may be coplanar with a side surface of the package substrate 100.

In some example embodiments, the molding layer 700 may be formed after the first semiconductor chip 200 is mounted on the package substrate 100.

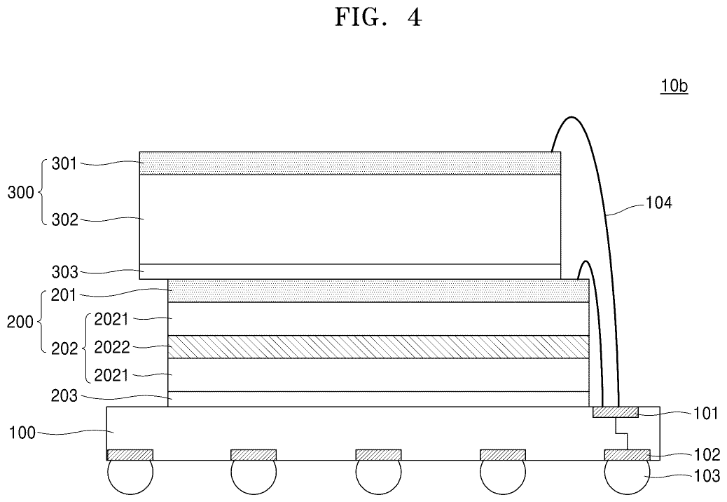

FIG. 4 is a schematic cross-sectional view of a semiconductor package 10b according to some example embodiments.

Referring to FIG. 4, the semiconductor package 10b may include a package substrate 100, a first semiconductor chip 200, and a second semiconductor chip 300.

Hereinafter, redundant descriptions between the semiconductor package 10b of FIG. 4 and the semiconductor package 10 (see FIG. 1) of FIG. 1 are omitted, and differences are described.

The package substrate 100 and the first semiconductor chip 200 of the semiconductor package 10b in FIG. 4 may be substantially the same as the package substrate 100 (see FIG. 1) and the first semiconductor chip 200 (see FIG. 1) of the semiconductor package 10 (see FIG. 1) in FIG. 1.

The second semiconductor chip 300 may be positioned over the first semiconductor chip 200. That is, the second semiconductor chip 300 may be mounted on the first semiconductor chip 200. In some example embodiments, the second semiconductor chip 300 may be offset-stacked with the first semiconductor chip 200. That is, the second semiconductor chip 300 and the first semiconductor chip 200 may be stacked in a cascade structure. In other words, the first semiconductor chip 200 and the second semiconductor chip 300 may be stacked in a stepped shape.

The second semiconductor chip 300 may be electrically connected to the package substrate 100. Although FIG. 4 illustrates that the second semiconductor chip 300 and upper connection pads 101 of the package substrate 100 are electrically connected to each other via a wire 104, the inventive concept is not limited thereto. The second semiconductor chip 300 may be electrically connected to the first semiconductor chip 200 via the wire 104.

In some example embodiments, an adhesive layer 303 may be between the first semiconductor chip 200 and the second semiconductor chip 300. The second semiconductor chip 300 may be attached onto the first semiconductor chip 200 through the adhesive layer 303. For example, the adhesive layer 303 may include an adhesive film such as a DAF.

The second semiconductor chip 300 may include a second active layer 301 and a second inactive layer 302.

The second active layer 301 may include a plurality of integrated elements. The plurality of integrated elements of the second active layer 301 may include memory elements or logic elements.

For example, the memory elements may include DRAM, SRAM, flash memory, EEPROM, PRAM, MRAM, and/or RRAM elements.

For example, the logic elements may include AND, NAND, OR, NOR, XOR, XNOR, INV, ADD, BUF, DLY, FIL, MXT/MXIT, OAI, AO, AOI, D flip-flop, reset flip-flop, master-slaver flip-flop, latch, counter, or buffer elements. Also, the logic elements may include a CPU, a MPU, a GPU, and/or an AP.

The second inactive layer 302 may include Si. However, a material of the second inactive layer 302 is not limited to Si. For example, the second inactive layer 302 may include another semiconductor element such as Ge, or a compound semiconductor such as SiC, GaAs, InAs, InP, and/or the like.

The second inactive layer 302 may have a SOI structure. For example, the second inactive layer 302 may include a BOX layer. Also, the second inactive layer 302 may include various element isolation structures such as a STI structure.

In some example embodiments, a density of the second inactive layer 302 may be substantially constant. That is, the second inactive layer 302 of the second semiconductor chip 300 may not be doped with high-density impurities. The density of the second inactive layer 302 may be substantially the same as a density of a reference region 2021 of the first inactive layer 202. That is, the density of the second inactive layer 302 may be lower than a density of a high-density region 2022 of the first inactive layer 202.

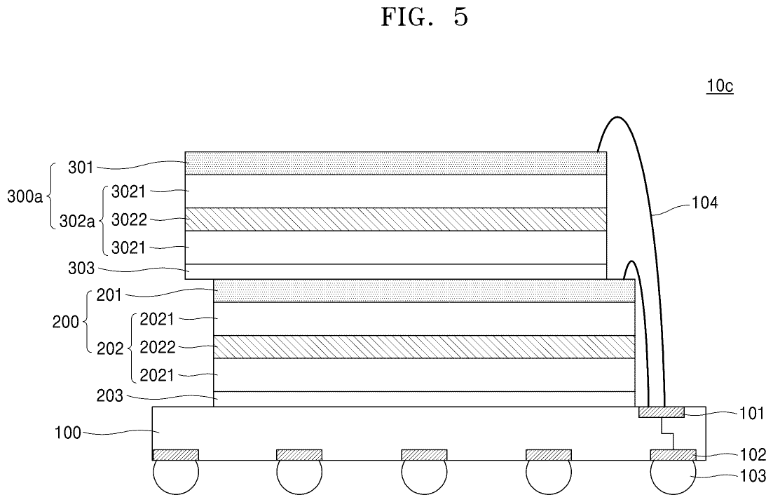

FIG. 5 is a schematic cross-sectional view of a semiconductor package 10c according to some example embodiments.

Referring to FIG. 5, the semiconductor package 10c may include a package substrate 100, a first semiconductor chip 200, and a second semiconductor chip 300a.

Hereinafter, redundant descriptions between the semiconductor package 10c of FIG. 5 and the semiconductor package 10b (see FIG. 4) of FIG. 4 are omitted, and differences are described.

The package substrate 100 and the first semiconductor chip 200 of the semiconductor package 10c in FIG. 5 may be substantially the same as the package substrate 100 (see FIG. 4) and the first semiconductor chip 200 (see FIG. 4) of the semiconductor package 10b (see FIG. 4) in FIG. 4.

The second semiconductor chip 300a may be positioned over the first semiconductor chip 200. That is, the second semiconductor chip 300a may be mounted on the first semiconductor chip 200. In some example embodiments, the second semiconductor chip 300a may be offset-stacked with the first semiconductor chip 200.

In some example embodiments, an adhesive layer 303 may be between the first semiconductor chip 200 and the second semiconductor chip 300a. The second semiconductor chip 300a may be attached onto the first semiconductor chip 200 through the adhesive layer 303. For example, the adhesive layer 303 may include an adhesive film such as a DAF.

The second semiconductor chip 300a may include a second active layer 301 and a second inactive layer 302a.

The second active layer 301 may include a plurality of integrated elements. The plurality of integrated elements of the second active layer 301 may include memory elements or logic elements. The second active layer 301 may be formed on the second inactive layer 302a. That is, the second active layer 301 may be spaced apart from the first active layer 201 with the second inactive layer 302a therebetween.

The second inactive layer 302 may include Si. However, a material of the second inactive layer 302 is not limited to Si. For example, the second inactive layer 302 may include another semiconductor element such as Ge, or a compound semiconductor such as SiC, GaAs, InAs, InP, and/or the like.

The second inactive layer 302a may include a reference region 3021 and a high-density region 3022. The high-density region 3022 may be a region doped with high-density impurities, and the reference region 3021 may be a region not doped with high-density impurities. That is, a density of the high-density region 3022 may be higher than a density of the reference region 3021.

The reference region 3021 may be positioned over and under the high-density region 3022. That is, the high-density region 3022 may be spaced apart from the second active layer 301 with the reference region 3021 therebetween. For example, the second active layer 301 may not be in contact with the high-density region 3022 of the second inactive layer 302a.

In some example embodiments, the high-density region 3022 of the second inactive layer 302a may be between the second active layer 301 and the first active layer 201. For example, the high-density region 2022 of the first inactive layer 202 and the high-density region 3022 of the second inactive layer 302a may be between the second active layer 301 and the package substrate 100.

In some example embodiments, the density of the high-density region 3022 of the second inactive layer 302a may be higher than a density of the reference region 2021 of the first inactive layer 202. The density of the high-density region 3022 of the second inactive layer 302a may be substantially the same as a density of the high-density region 2022 of the first inactive layer 202. High-density impurities doped in the high-density region 3022 of the second inactive layer 302a may be different from high-density impurities doped in the high-density region 2022 of the first inactive layer 202.

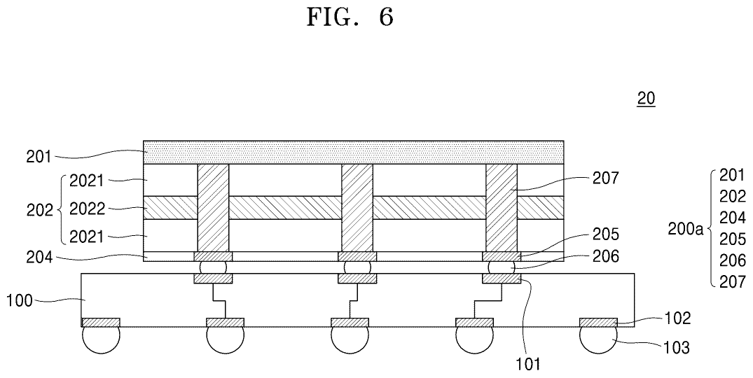

FIG. 6 is a schematic cross-sectional view of a semiconductor package 20 according to some example embodiments.

Referring to FIG. 6, the semiconductor package 20 may include a package substrate 100 and a first semiconductor chip 200a.

Hereinafter, redundant descriptions between the semiconductor package 20 of FIG. 6 and the semiconductor package 10 (see FIG. 1) of FIG. 1 are omitted, and differences are described.

The package substrate 100 of the semiconductor package 20 in FIG. 6 may be substantially the same as the package substrate 100 (see FIG. 1) of the semiconductor package 10 (see FIG. 1) in FIG. 1.

The first semiconductor chip 200a may include a first active layer 201, a first inactive layer 202, through-vias 207, an insulating layer 204, first lower bonding pads 205, and external connection terminals 206.

The first active layer 201 may include a plurality of integrated elements. The plurality of integrated elements of the first active layer 201 may include memory elements or logic elements. The first active layer 201 may be spaced apart from the package substrate 100 with the first inactive layer 202 therebetween.

The first inactive layer 202 may include Si. However, a material of the first inactive layer 202 is not limited to Si. For example, the first inactive layer 202 may include another semiconductor element such as Ge, or a compound semiconductor such as SiC, GaAs, InAs, InP, and/or the like.

The first inactive layer 202 may include a reference region 2021 and a high-density region 2022. The high-density region 2022 may be a region doped with high-density impurities, and the reference region 2021 may be a region not doped with high-density impurities. That is, a density of the high-density region 2022 may be higher than a density of the reference region 2021.

In some example embodiments, the high-density region 2022 of the first inactive layer 202 may be between the first active layer 201 and the package substrate 100. The first active layer 201 may be spaced apart from the package substrate 100 with the high-density region 2022 therebetween.

The first lower bonding pads 205 may be provided on the first semiconductor chip 200a. For example, the first lower bonding pads 205 may be positioned under the first inactive layer 202 of the first semiconductor chip 200a. The external connection terminals 206 may be attached to the first lower bonding pads 205, respectively.

The external connection terminals 206 may be configured to electrically and physically connect the package substrate 100 and the first semiconductor chip 200a to each other. The external connection terminals 206 may be formed from, for example, solder balls or solder bumps. The external connection terminals 206 may electrically connect upper connection pads 101 on the package substrate 100 to the first lower bonding pads 205 of the first semiconductor chip 200a.

In some example embodiments, the first lower bonding pads 205 may each include a metal or an alloy thereof, the metal including Cu, Al, W, Ti, Ta, In, Mo, Mn, Co, Sn, Ni, Mg, Re, Be, Ga, and/or Ru.

The insulating layer 204 may surround side surfaces of the first lower bonding pads 205. That is, the insulating layer 204 may include an opening to expose a portion of each of the first lower bonding pads 205 to the outside. The first lower bonding pads 205 may be in contact with the external connection terminals 206 through openings in the insulating layer 204.

For example, the insulating layer 204 may include silicon nitride (SiN), silicon oxide (SiO), silicon carbon nitride (SiCN), silicon boron nitride (SiBN), silicon oxynitride (SiON), silicon oxycarbonitride (SiOCN), silicon boron carbonitride (SiBCN), silicon oxycarbide (SiOC), or a combination thereof.

The through-vias 207 may pass through at least portions of the first semiconductor chip 200a. The through-vias 207 may electrically connect the first active layer 201 and package substrate 100 to each other. In detail, the through-via 207 may electrically connect the first lower bonding pads 205 to the first active layer 201. The through-via 207 may extend through the high-density region 2022 and/or the reference region 2021.

For example, the through-vias 207 may each include a conductive material such as Cu, silver (Ag), gold (Au), W, Al, Ti, Ta, or a combination thereof.

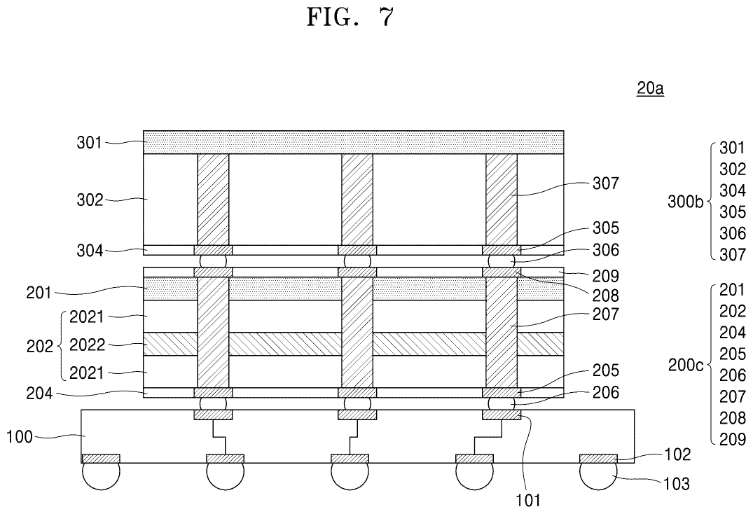

FIG. 7 is a schematic cross-sectional view of a semiconductor package 20a according to some example embodiments.

Referring to FIG. 7, the semiconductor package 20a may include a package substrate 100, a first semiconductor chip 200c, and a second semiconductor chip 300b.

Hereinafter, redundant descriptions between the semiconductor package 20a of FIG. 7 and the semiconductor package 20 (see FIG. 6) of FIG. 6 are omitted, and differences are described.

The package substrate 100 of the semiconductor package 20a in FIG. 7 may be substantially the same as the package substrate 100 (see FIG. 6) of the semiconductor package 20 (see FIG. 6) in FIG. 6.

The first semiconductor chip 200c may include a first active layer 201, a first inactive layer 202, through-vias 207, an insulating layer 204, first lower bonding pads 205, a passivation layer 209, first upper bonding pads 208, and external connection terminals 206.

The first active layer 201, the first inactive layer 202, the insulating layer 204, and the first lower bonding pads 205, and the external connection terminals 206 may be substantially the same as those described with reference to FIG. 6.

The first upper bonding pads 208 may be provided on the first semiconductor chip 200c. For example, the first upper bonding pads 208 may be positioned on an upper surface of the first active layer 201 of the first semiconductor chip 200c. External connection terminals 306 to be described below may be attached to the first upper bonding pads 208.

In some example embodiments, the first upper bonding pads 208 may each include a metal or an alloy thereof, the metal including Cu, Al, W, Ti, Ta, In, Mo, Mn, Co, Sn, Ni, Mg, Re, Be, Ga, and Ru.

The first upper bonding pads 208 may be exposed by the passivation layer 209 that protects the first active layer 201. In detail, at least some of the first upper bonding pads 208 may be exposed to the outside through openings of the passivation layer 209. That is, the passivation layer 209 may cover portions of the first upper bonding pads 208.

In some example embodiments, the passivation layer 209 may include an insulating material such as photosensitive polyimide (PSPI), SiN, and/or SiO.

The through-vias 207 may electrically connect the first lower bonding pads 205 and the first upper bonding pads 208 to each other, respectively. The package substrate 100 and the second semiconductor chip 300b to be described below may be electrically connected to each other through the through-vias 207.

The second semiconductor chip 300b may be positioned on the first semiconductor chip 200c. That is, the second semiconductor chip 300b may be mounted on the first semiconductor chip 200c. In some example embodiments, the second semiconductor chip 300b may overlap an upper surface of the first semiconductor chip 200c.

In some example embodiments, the second semiconductor chip 300b may be mounted on the first semiconductor chip 200c so that a second active layer 301 of the second semiconductor chip 300b faces the first active layer 201 of the first semiconductor chip 200c. In addition, the second semiconductor chip 300b may be mounted on the first semiconductor chip 200c so that a second inactive layer 302 of the second semiconductor chip 300b faces the first active layer 201 of the first semiconductor chip 200c.

The second semiconductor chip 300b may include the second active layer 301, the second inactive layer 302, and second lower bonding pads 305.

The second active layer 301 may include a plurality of integrated elements. The plurality of integrated elements of the second active layer 301 may include memory elements or logic elements.

The second inactive layer 302 may include Si. However, a material of the second inactive layer 302 is not limited to Si. For example, the second inactive layer 302 may include another semiconductor element such as Ge, or a compound semiconductor such as SiC, GaAs, InAs, InP, and/or the like.

The second inactive layer 302 may have a SOI structure. For example, the second inactive layer 302 may include a BOX layer. Also, the second inactive layer 302 may include various element isolation structures such as a STI structure.

As shown in FIG. 7, the second inactive layer 302 may have a constant density. However, the inventive concept is not limited thereto. The second inactive layer 302 may include a high-density region having a relative high density. For example, the second inactive layer 302 may include a buried doped region doped with high-density impurities HDM (see high-density region 2022 of first semiconductor chip 200c).

The second lower bonding pads 305 may be arranged to face the first upper bonding pads 208. The external connection terminals 306 may be attached to the second lower bonding pads 305, and accordingly, the second lower bonding pads 305 and the first upper bonding pads 208 may be electrically connected to each other. The external connection terminals 306 may be formed from, for example, solder balls or solder bumps.

The second lower bonding pads 305 may be surrounded by a protective layer 304. The protective layer 304 may be a passivation layer or an insulating layer. The protective layer 304 may suppress an electrical short between the second lower bonding pads 305 and physically protect the second semiconductor chip 300b.

In some example embodiments, the second lower bonding pads 305 may each include a metal or an alloy thereof, the metal including Cu, Al, W, Ti, Ta, In, Mo, Mn, Co, Sn, Ni, Mg, Re, Be, Ga, and/or Ru.

As shown in FIG. 7, when the second semiconductor chip 300b is mounted on the first semiconductor chip 200c so that the second inactive layer 302 faces the first active layer 201, the second lower bonding pads 305 may be positioned under the second inactive layer 302. The second active layer 301 may be electrically connected to the second lower bonding pads 305 through through-vias 307 passing through portions of the second semiconductor chip 300b. That is, the through-vias 307 may be in contact with the second lower bonding pads 305 and the second active layer 301 and thus finally electrically connect the package substrate 100 and the second semiconductor chip 300b to each other. In this case, the protective layer 304 may be an insulating layer positioned under the first inactive layer 202.

In another example embodiment, when the second semiconductor chip 300b is mounted on the first semiconductor chip 200c so that the second active layer 301 faces the first active layer 201, the second lower bonding pads 305 may be positioned under the second active layer 301. The second active layer 301 may be electrically connected to the first semiconductor chip 200c through the second lower bonding pads 305 and the external connection terminals 306. Finally, the second active layer 301 may be electrically connected to the package substrate 100. In this case, the protective layer 304 may be a passivation layer positioned under the first active layer 201.

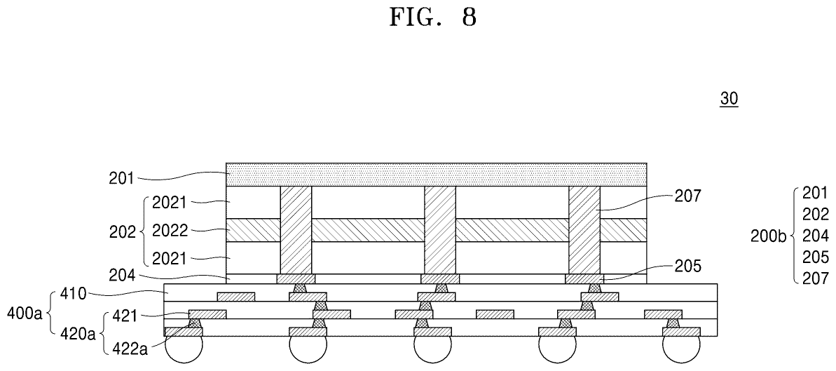

FIG. 8 is a schematic cross-sectional view of a semiconductor package 30 according to example embodiments.

Referring to FIG. 8, the semiconductor package 30 may include a redistribution structure 400a and a first semiconductor chip 200b.

The redistribution structure 400a may include a redistribution insulating layer 410 and a plurality of redistribution patterns 420a. The redistribution insulating layer 410 may surround the plurality of redistribution patterns 420a. In some example embodiments, the redistribution structure 400a may include a plurality of redistribution insulating layers 410 stacked on one another. The redistribution insulating layers 410 may each include, for example, a photo-imagable dielectric (PID) or PSPI. For example, the redistribution structure 400a may have a thickness of about 30 μm to about 50 μm.

The plurality of redistribution patterns 420a may include a plurality of redistribution line patterns 421 and a plurality of redistribution via patterns 422a, respectively. The plurality of redistribution patterns 420a may each include, for example, a metal or a metal alloy, the metal including Cu, Al, W, Ti, Ta, In, Mo, Mn, Co, Sn, Ni, Mg, Re, Be, Ga, and/or Ru, but are not limited thereto. In some example embodiments, the plurality of redistribution patterns 420a may each be formed by stacking metals or metal alloys on a seed layer including Cu, Ti, titanium nitride (TiN), or titanium tungsten (TiW).

The plurality of redistribution line patterns 421 may be arranged on at least one of upper and lower surfaces of the redistribution insulating layer 410. For example, when the redistribution structure 400a includes the plurality of redistribution insulating layers 410 stacked on one another, the plurality of redistribution line patterns 421 may be arranged on at least some portions of an upper surface of the uppermost redistribution insulating layer 410, a lower surface of the lowermost redistribution insulating layer 410, and between two adjacent redistribution insulating layers 410 among the plurality of redistribution insulating layers 410.

The plurality of redistribution via patterns 422a may be in contact with and connected to some of the plurality of redistribution line patterns 421 through at least one redistribution insulating layer 410, respectively.

The plurality of redistribution via patterns 422a may each have a tapered shape extending from the bottom surface to the top surface with a horizontal width thereof decreasing. For example, horizontal widths of the plurality of redistribution via patterns 422a may decrease in a direction toward the first semiconductor chip 200b.

The semiconductor package 30 may be manufactured using a chip first method. A method of forming the redistribution structure 400a on the first semiconductor chip 200b after the first semiconductor chip 200b is first manufactured is referred to as the chip first method. That is, the chip first method is a method of manufacturing redistribution insulating layers and redistribution patterns on first lower bonding pads 205 and an insulating layer 204 of the first semiconductor chip 200b by flipping the first semiconductor chip 200b. Accordingly, the redistribution via patterns 422a of the redistribution patterns 420a may each have an inclined side surface having a greater width in a direction away from the first semiconductor chip 200b.

That is, in the semiconductor package 30 manufactured using the chip first method, the first lower bonding pads 205 and the insulating layer 204 of the first semiconductor chip 200b are in direct contact with the redistribution structure 400a, and accordingly, the first semiconductor chip 200b and the redistribution structure 400a may be electrically connected to each other.

The first semiconductor chip 200b may include a first active layer 201, a first inactive layer 202, first lower bonding pads 205, an insulating layer 204, and through-vias 207. The first active layer 201, the first lower bonding pads 205, the insulating layer 204, and the through-vias 207 of the first semiconductor chip 200b may correspond to the first active layer 201 (see FIG. 6), the first lower bonding pads 205 (see FIG. 6), the insulating layer 204 (see FIG. 6), and the through-vias 207 (see FIG. 6).

The first inactive layer 202 may include a high-density region 2022 having a higher density than those of other regions of the first inactive layer 202. That is, the first inactive layer 202 may include regions having different densities. The first inactive layer 202 may include the high-density region 2022 and a reference region 2021. The reference region 2021 of the first inactive layer 202 may be a region that does not correspond to the high-density region 2022 of the first inactive layer 202. A density of the high-density region 2022 may be higher than a density of the reference region 2021.

In the semiconductor package 30 manufactured using the chip first method, the first lower bonding pads 205 are in direct contact with the redistribution patterns 420a, respectively, and accordingly, the redistribution structure 400a and the first semiconductor chip 200b may be directly connected to each other.

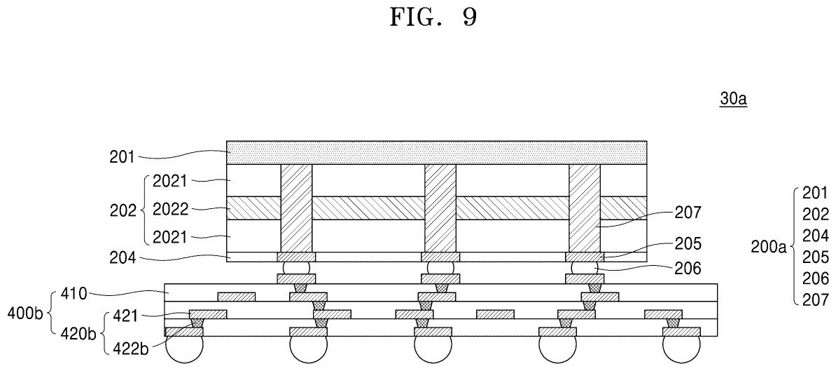

FIG. 9 is a schematic cross-sectional view of a semiconductor package 30a according to some example embodiments.

Referring to FIG. 9, the semiconductor package 30a may include a redistribution structure 400b and a first semiconductor chip 200a.

Hereinafter, redundant descriptions between the semiconductor package 30a of FIG. 9 and the semiconductor package 30 of FIG. 8 are omitted, and differences are described.

The semiconductor package 30a of FIG. 9 may be the semiconductor package 30a in which the first semiconductor chip 200a and the redistribution structure 400b are connected to each other using a chip last method. The chip last method is a method of mounting the first semiconductor chip 200a on the redistribution structure 400b after the redistribution structure 400b is manufactured.

The redistribution structure 400b may include a redistribution insulating layer 410 and a plurality of redistribution patterns 420b. The redistribution insulating layer 410 may surround the plurality of redistribution patterns 420b. In some example embodiments, the redistribution structure 400b may include a plurality of redistribution insulating layers 410 stacked on one another.

A plurality of redistribution line patterns 421 may be arranged on at least one of upper and lower surfaces of the redistribution insulating layer 410. A plurality of redistribution via patterns 422b may be in contact with and connected to some of the plurality of redistribution line patterns 421 through at least one redistribution insulating layer 410, respectively.

The plurality of redistribution via patterns 422b may each have a tapered shape extending from the top surface to the bottom surface with a horizontal width thereof decreasing. For example, horizontal widths of the plurality of redistribution via patterns 422b may increase in a direction toward the first semiconductor chip 200a. That is, in the chip last method, the redistribution insulating layer 410 and the redistribution patterns 420b are first generated, the redistribution insulating layer 410 and the redistribution patterns 420b being positioned far from a surface of the redistribution structure 400b on which the first semiconductor chip 200a is mounted. Accordingly, widths of the redistribution via patterns 422b of the redistribution patterns 420b may increase in a direction toward the surface of the redistribution structure 400b on which the first semiconductor chip 200a is mounted.

The first semiconductor chip 200a may be mounted on the redistribution structure 400b using a flip chip method. That is, in the first semiconductor chip 200a, external connection terminals 206 are attached to first lower bonding pads 205 and redistribution line patterns 421, and accordingly, the first semiconductor chip 200a and the redistribution structure 400b may be electrically connected to each other. The external connection terminals 206 may be formed from, for example, solder balls or solder bumps.

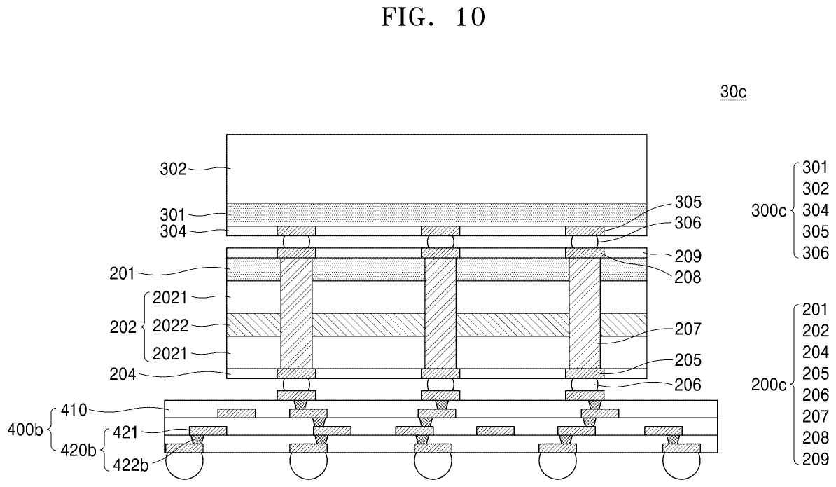

FIG. 10 is a schematic cross-sectional view of a semiconductor package 30c according to some example embodiments.

The semiconductor package 30c of FIG. 10 may include a redistribution structure 400b, a first semiconductor chip 200c, and a second semiconductor chip 300c.

Hereinafter, redundant descriptions between the semiconductor package 30c of FIG. 10 and the semiconductor package 30a (see FIG. 9) of FIG. 9 are omitted, and differences are described.

The redistribution structure 400b may be substantially the same as the redistribution structure 400b (see FIG. 9) described with reference to FIG. 9.

The first semiconductor chip 200c may include a first active layer 201, a first inactive layer 202, first lower bonding pads 205, first upper bonding pads 208, an insulating layer 204, and a passivation layer 209. The first lower bonding pads 205 may be positioned under the first inactive layer 202 and surrounded by the insulating layer 204. The first upper bonding pads 208 may be positioned on the first active layer 201 and surrounded by the passivation layer 209. The first upper bonding pads 208 and the first lower bonding pads 205 may be connected to each other through through-vias 207.

The first active layer 201 may include a plurality of integrated elements. The first inactive layer 202 may include a reference region 2021 and a high-density region 2022. The high-density region 2022 may be positioned inside the first inactive layer 202 without being in contact with the first active layer 201. The high-density region 2022 may be a region doped with high-density impurities having a higher density than that of the reference region 2021.

The second semiconductor chip 300c may include a second active layer 301 and a second inactive layer 302. The second semiconductor chip 300c may be stacked on the first semiconductor chip 200c so that the second active layer 301 faces the first active layer 201.

In detail, second lower bonding pads 305 and a protective layer 304 may be positioned under the second active layer 301. The protective layer 304 may surround at least some of the second lower bonding pads 305. External connection terminals 306 may be mounted on the second lower bonding pads 305, respectively. The second lower bonding pads 305 and the first upper bonding pads 208 may be electrically connected to each other through the external connection terminals 306, respectively.

In some example embodiments, a density of the second inactive layer 302 may be constant in all regions. The density of the second inactive layer 302 may be substantially the same as a density of the reference region 2021 of the first inactive layer 202.

In some example embodiments, the second inactive layer 302 may include a high-density region. The high-density region may have a higher density than those of other regions of the second inactive layer 302.

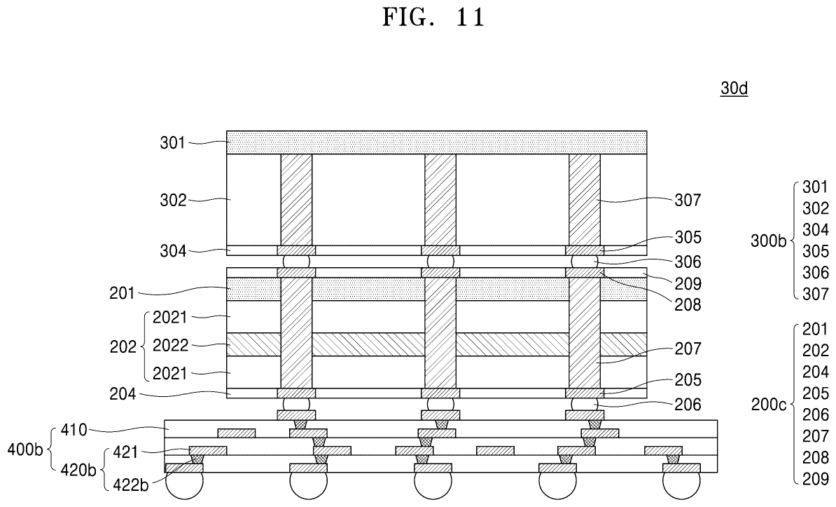

FIG. 11 is a schematic cross-sectional view of a semiconductor package 30d according to some example embodiments.

The semiconductor package 30d of FIG. 11 may include a redistribution structure 400b, a first semiconductor chip 200c, and a second semiconductor chip 300b.

Hereinafter, redundant descriptions between the semiconductor package 30d of FIG. 11 and the semiconductor package 30c (see FIG. 11) of FIG. 11 are omitted, and differences are described.

The redistribution structure 400b and the first semiconductor chip 200c may be substantially the same as the redistribution structure 400b (see FIG. 10) and the first semiconductor chip 200c (see FIG. 10) described with reference to FIG. 10.

The second semiconductor chip 300b may include a second active layer 301 and a second inactive layer 302. The second semiconductor chip 300b may be mounted on the first semiconductor chip 200c so that the second inactive layer 302 faces a first active layer 201.

The second semiconductor chip 300b may include second lower bonding pads 305 and a protective layer 304 positioned under the second inactive layer 302. The protective layer 304 may surround at least some of the second lower bonding pads 305. External connection terminals 306 may be mounted on the second lower bonding pads 305, respectively. The second lower bonding pads 305 and first upper bonding pads 208 may be electrically connected to each other through the external connection terminals 306, respectively.

Through-vias 307 may electrically connect the second lower bonding pads 305 to the second active layer 301. That is, the second active layer 301 spaced apart from the first active layer 201 with the second inactive layer 302 therebetween may be electrically connected to the redistribution structure 400b through the through-vias 307.

In some example embodiments, a density of the second inactive layer 302 may be constant in all regions. The density of the second inactive layer 302 may be substantially the same as a density of a reference region 2021 of a first inactive layer 202.

In some example embodiments, the second inactive layer 302 may include a high-density region. The high-density region may have a higher density than those of other regions of the second inactive layer 302. The high-density region may be between the second active layer 301 and the first active layer 201, not to be in contact with the second active layer 301. For example, the second inactive layer 302 may include a buried doped region doped with high-density impurities HDM (see high-density region 2022 of first semiconductor chip 200c).

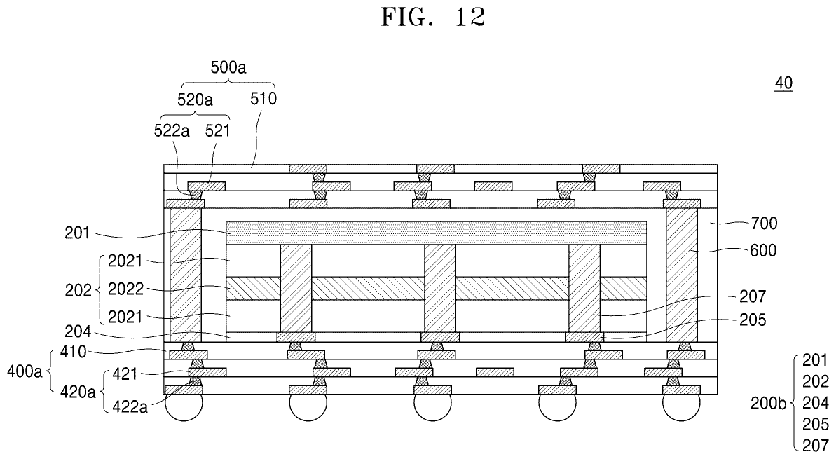

FIG. 12 is a schematic cross-sectional view of a semiconductor package 40 according to some example embodiments.

Referring to FIG. 12, the semiconductor package 40 may include a first redistribution structure 400a, a first semiconductor chip 200b, and a second redistribution structure 500a. The first redistribution structure 400a may be referred to as a lower redistribution structure, and the second redistribution structure 500a may be referred to as an upper redistribution structure.

Hereinafter, redundant descriptions between the semiconductor package 40 of FIG. 12 and the semiconductor package 30 (see FIG. 8) of FIG. 8 are omitted, and differences are described.

The second redistribution structure 500a may be arranged over the first semiconductor chip 200b. In other words, the second redistribution structure 500a may be stacked on a molding layer 700 surrounding the first semiconductor chip 200b.

The second redistribution structure 500a may include a redistribution insulating layer 510 and a plurality of redistribution patterns 520a. The redistribution insulating layer 510 may surround the plurality of redistribution patterns 520a. In some example embodiments, the second redistribution structure 500a may include a plurality of redistribution insulating layers 510 stacked on one another.

The redistribution insulating layers 510 may each include, for example, a PID or PSPI. For example, the second redistribution structure 500a may have a thickness of about 30 μm to about 50 μm.

The plurality of redistribution patterns 520a may include a plurality of redistribution line patterns 521 and a plurality of redistribution via patterns 522a, respectively. The plurality of redistribution patterns 520a may each include, for example, a metal or a metal alloy, the metal including Cu, Al, W, Ti, Ta, In, Mo, Mn, Co, Sn, Ni, Mg, Re, Be, Ga, and/or Ru, but are not limited thereto. In some example embodiments, the plurality of redistribution patterns 520a may each be formed by stacking metals or metal alloys on a seed layer including Cu, Ti, TiN, or TiW.

The plurality of redistribution line patterns 521 may be arranged on at least one of upper and lower surfaces of the redistribution insulating layer 510. For example, when the second redistribution structure 500a includes the plurality of redistribution insulating layers 510 stacked on one another, the plurality of redistribution line patterns 521 may be arranged on at least some portions of an upper surface of the uppermost redistribution insulating layer 510, a lower surface of the lowermost redistribution insulating layer 510, and between two adjacent redistribution insulating layers 510 among the plurality of redistribution insulating layers 510.

The plurality of redistribution via patterns 522a may be in contact with and connected to some of the plurality of redistribution line patterns 521 through at least one redistribution insulating layer 510, respectively.

In some example embodiments, the plurality of redistribution via patterns 522a may each have a tapered shape extending from the bottom surface to the top surface with a horizontal width thereof increasing. For example, horizontal widths of the plurality of redistribution via patterns 522a may increase in a direction away from the first semiconductor chip 200b. However, the inventive concept is not limited thereto. The plurality of redistribution via patterns 522a may each have a tapered shape extending from the bottom surface to the top surface with a horizontal width thereof decreasing.

Conductive posts 600 may connect the first redistribution structure 400a and the second redistribution structure 500a to each other. The conductive posts 600 may electrically connect the redistribution patterns 420a of the first redistribution structure 400a and the redistribution patterns 520a of the second redistribution structure 500a to each other through the molding layer 700.

For example, the conductive posts 600 may each include, for example, a metal or a metal alloy, the metal including Cu, Al, W, Ti, Ta, In, Mo, Mn, Co, Sn, Ni, Mg, Re, Be, Ga, and/or Ru, but are not limited thereto.

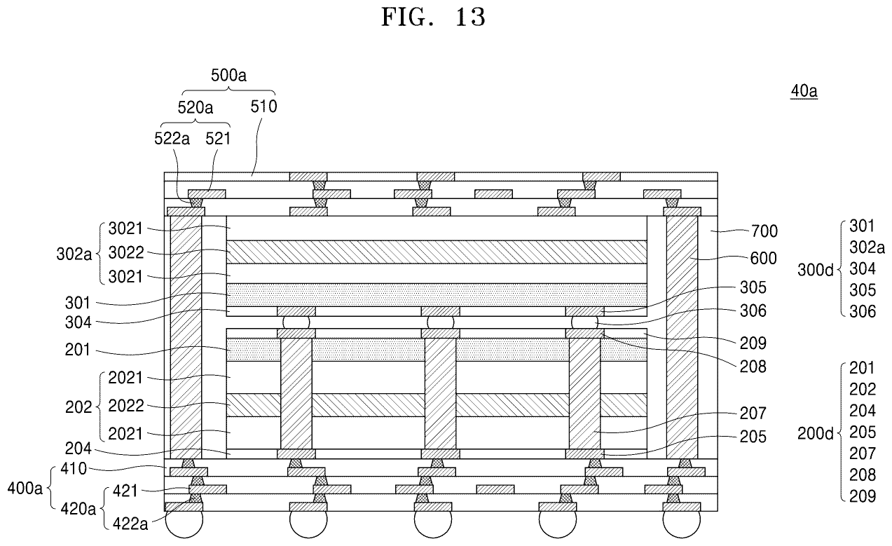

FIG. 13 is a schematic cross-sectional view of a semiconductor package 40a according to some example embodiments.

Referring to FIG. 13, the semiconductor package 40a may include a first redistribution structure 400a, a first semiconductor chip 200d, a second semiconductor chip 300d, and a second redistribution structure 500a.

Hereinafter, redundant descriptions between the semiconductor package 40a of FIG. 13 and the semiconductor package 40 (see FIG. 12) of FIG. 12 are omitted, and differences are described.

The first semiconductor chip 200d, the second semiconductor chip 300d, and the second redistribution structure 500a may be stacked on the first redistribution structure 400a. A molding layer 700 may fill an empty space between the first redistribution structure 400a and the second redistribution structure 500a. That is, the molding layer 700 may surround the first semiconductor chip 200d and the second semiconductor chip 300d.

Conductive posts 600 may electrically connect the first redistribution structure 400a and the second redistribution structure 500a to each other. In detail, the conductive posts 600 may be in contact with redistribution patterns 420a of the first redistribution structure 400a and redistribution patterns 520a of the second redistribution structure 500a. The conductive posts 600 may connect the redistribution patterns 420a of the first redistribution structure 400a and redistribution patterns 520a to each other through the molding layer 700.

The second semiconductor chip 300d may be stacked on the first semiconductor chip 200d. In detail, the second semiconductor chip 300d may be stacked on the first semiconductor chip 200d so that second lower bonding pads 305 of the second semiconductor chip 300d overlap corresponding first upper bonding pads 208 of the first semiconductor chip 200d, respectively.

The first semiconductor chip 200d and the second semiconductor chip 300d may be electrically connected to each other by external connection terminals 306 between the second lower bonding pads 305 and the first upper bonding pads 208.

The second semiconductor chip 300d may include a second active layer 301 and a second inactive layer 302a, the second active layer 301 including integrated elements. In some example embodiments, the second semiconductor chip 300d may correspond to the second semiconductor chip 300b (see FIG. 7) or the second semiconductor chip 300c (see FIG. 10) described above.

In some example embodiments, the second semiconductor chip 300d may be stacked on the first semiconductor chip 200d so that the second active layer 301 faces the first active layer 201. In addition, the second semiconductor chip 300d may be stacked on the first semiconductor chip 200d so that the second inactive layer 302a faces the first active layer 201.

In some example embodiments, the second inactive layer 302a may include a reference region 3021 and a high-density region 3022. The high-density region 3022 may be a region doped with high-density impurities having a higher density than that of the reference region 3021. The high-density region 3022 may have a thickness of about 1 μm to about 7 μm.

In some example embodiments, a density of the second inactive layer 302a may be constant in all regions. That is, the second inactive layer 302a may not be doped with high-density impurities.

The inventive concepts have been described above with reference to the example embodiments shown in the accompanying drawings, but these are merely examples. Therefore, those of ordinary skill in the art will understand that various modifications and other equivalent example embodiments may be made therefrom. Accordingly, the true technical scope of protection of the inventive concepts should be determined by the technical spirit of the appended claims.

While the inventive concepts have been particularly shown and described with reference to example embodiments thereof, it will be understood that various changes in form and details may be made therein without departing from the spirit and scope of the following claims. No example embodiment is necessarily mutually exclusive with any other example embodiment. For example, some example embodiments may include features described with reference to one or more figures.

What is claimed is:

1. A semiconductor package comprising:
a package substrate; and
a first semiconductor chip on the package substrate, the first semiconductor chip including a first inactive layer and a first active layer,
wherein the first inactive layer includes a high-density region, and
the high-density region of the first inactive layer has a higher density than densities of other regions of the first inactive layer.

2. The semiconductor package of claim 1, wherein
the first active layer is spaced apart from the package substrate and
the first inactive layer is between the package substrate and the first active layer.

3. The semiconductor package of claim 1, wherein the high-density region of the first inactive layer is spaced apart from the first active layer.

4. The semiconductor package of claim 1, wherein the high-density region of the first inactive layer extends in a direction parallel to a lower surface of the first inactive layer.

5. The semiconductor package of claim 1, wherein a thickness of the high-density region is about 3 μm to about 7 μm.

6. The semiconductor package of claim 1, wherein a thickness of the first semiconductor chip is about 40 μm to about 60 μm.

7. The semiconductor package of claim 1, wherein the high-density region is doped with high-density impurities having a higher density than silicon.

8. The semiconductor package of claim 1, further comprising:
a molding layer on the package substrate, the molding layer surrounding the first semiconductor chip.

9. The semiconductor package of claim 1, wherein a density of the high-density region of the first semiconductor chip gradually decreases in a direction away from the package substrate.

10. The semiconductor package of claim 1, further comprising:
a second semiconductor chip on the first semiconductor chip.

11. The semiconductor package of claim 10, wherein the second semiconductor chip includes a second active layer and a second inactive layer, and
the second inactive layer has a constant density.

12. The semiconductor package of claim 11, wherein a density of the second inactive layer is lower than a density of the high-density region of the first inactive layer.

13. The semiconductor package of claim 10, wherein the second semiconductor chip includes a second active layer and a second inactive layer,
the second inactive layer includes a high-density region, and
a density of the high-density region of the second inactive layer is higher than densities of other regions of the second inactive layer.

14. The semiconductor package of claim 13, wherein
the second active layer is spaced apart from the first active layer, and
the second inactive layer is between the first active layer and the second active layer.

15. The semiconductor package of claim 14, wherein the high-density region of the second inactive layer is not in contact with the first active layer and the second active layer.

16. A semiconductor package comprising:
a redistribution structure; and
a semiconductor chip on the redistribution structure, the semiconductor chip including an inactive layer and an active layer,
wherein the inactive layer includes a buried doped region, the buried doped region is doped with high-density impurities, and
a density of the high-density impurities is higher than silicon.

17. The semiconductor package of claim 16, wherein the buried doped region is in the inactive layer and spaced apart from the active layer.

18. The semiconductor package of claim 16, further comprising:
a through-via passing through at least a portion of the semiconductor chip,
wherein the active layer is spaced apart from the redistribution structure, and
the through-via passes through the buried doped region of the inactive layer and is configured to electrically connect the active layer and the redistribution structure.

19. The semiconductor package of claim 16, wherein a horizontal width of the buried doped region is equal to a horizontal width of the active layer.

20. A semiconductor package comprising:
a package substrate;
a first semiconductor chip on the package substrate, the first semiconductor chip including a first inactive layer and a first active layer; and
a molding layer on the package substrate, the molding layer surrounding the first semiconductor chip,
wherein the first inactive layer includes a high-density region doped with high-density impurities having a higher density than silicon,
a density of the high-density region of the first inactive layer is higher than densities of other regions of the first inactive layer,
the high-density region is spaced apart from the first active layer and is between the package substrate and the first active layer, and
a concentration of the high-density impurities doped in the high-density region decreases in a direction toward the first active layer.
